(19) United States
(12) Patent Application Publication
(10) Pub. No.: US 2019/0371417 A1
(43) Pub. Date: Dec. 5, 2019

(54) PROGRAMMING METHOD FOR MEMORY DEVICE

(71) Applicant: MACRONIX INTERNATIONAL CO., LTD., Hsinchu (TW)

(72) Inventors: Chih-Chang HSIEH, Hsinchu City (TW); Yung-Chun LI, New Taipei City (TW); Ti-Wen CHEN, Tainan City (TW)

(21) Appl. No.: 15/991,133

(22) Filed: May 29, 2018

(51) Int. Cl. G11C 16/34; G11C 16/10; G11C 16/04; G11C 11/4074; G11C 11/56

(52) U.S. Cl. CPC G11C 16/3459; G11C 16/10; G11C 11/5628; G11C 11/4074; G11C 16/0483

(57) ABSTRACT

In programming a memory device, a target memory cell is programmed by a programming voltage and a programming code. First and second verification voltages are applied on the target memory cell to obtain first and second read data. Whether the target memory cell passes an actual programming verification and/or a pseudo programming verification is determined based on the programming code, the first and the second read data.

### TECHNICAL FIELD

The disclosure relates in general to a programming method for a memory device.

### BACKGROUND

Flash memory is a kind of a non-volatile memory device. By applying programming pulses to memory cells, data is stored into the memory cells.

In order to tighten threshold voltage (Vt) distribution of memory cells, during ISPP (Incremental Step Pulse Programming) operations, a programming step and one or more verifying steps are performed. The programming pulses are used to increase the threshold voltage of the memory cells. In ISPP, a program verify (PV) pulse is applied between the programming pulses, for verifying whether the memory cells are programmed successfully by verifying whether the threshold voltage of the memory cells exceed the programming verifying voltage. By so, ISPP operations may tighten the threshold voltage distribution.

Besides, the flash memory may be suffered by time dependent relaxation issues. The time dependent relaxation issues may cause increase or decrease of the threshold voltage of the memory cells, and thus the memory cells may not pass the verification or the Vt distribution may be wider.

Thus, there needs a programming method for a memory device to tighten Vt distribution of the memory cells.

### SUMMARY

According to one embodiment, a method for programming a memory device is provided. The method comprises: programming a target memory cell by a programming voltage and a programming code; applying first and second verification voltages on the target memory cell to obtain first and second read data; and determining whether the target memory cell pass an actual programming verification and/or a pseudo programming verification based on the programming code, the first and the second read data.

According to one embodiment, a method for programming a memory device is provided. The method comprises: executing a programming operation and a programming-verification operation on a target memory cell, the programming operation and the programming-verification operation including: applying a plurality of programming voltages, a plurality of first verification voltages and a plurality of second verification voltages on the target memory cell, wherein each of the first verification voltages and each of the second verification voltages is corresponding to a time dependent relaxation; and determining whether a threshold voltage of the target memory cell passes each of the first verification voltages and/or each of the second verification voltages to determine whether the target memory cell is successfully programmed.

### BRIEF DESCRIPTION OF THE DRAWINGS

FIG. 1 shows a programming method for a memory device according to a first embodiment of the application.

FIG. 2 shows a program sequence according to the first embodiment of the application.

FIG. 3 shows Vt distribution of SLC memory cells.

FIG. 4 shows a programming method for a memory device according to a second embodiment of the application.

FIG. 5 shows a program sequence according to the second embodiment of the application.

FIG. 6 shows Vt distribution of MLC memory cells.

FIG. 7 shows a programming method for a memory device according to a third embodiment of the application.

FIG. 8 shows a program sequence according to the third embodiment of the application.

FIG. 9 shows Vt distribution of TLC memory cells.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DESCRIPTION OF THE EMBODIMENTS

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, one skilled person in the art would selectively implement part or all technical features of any embodiment of the disclosure or selectively combine part or all technical features of the embodiments of the disclosure.

### First Embodiment

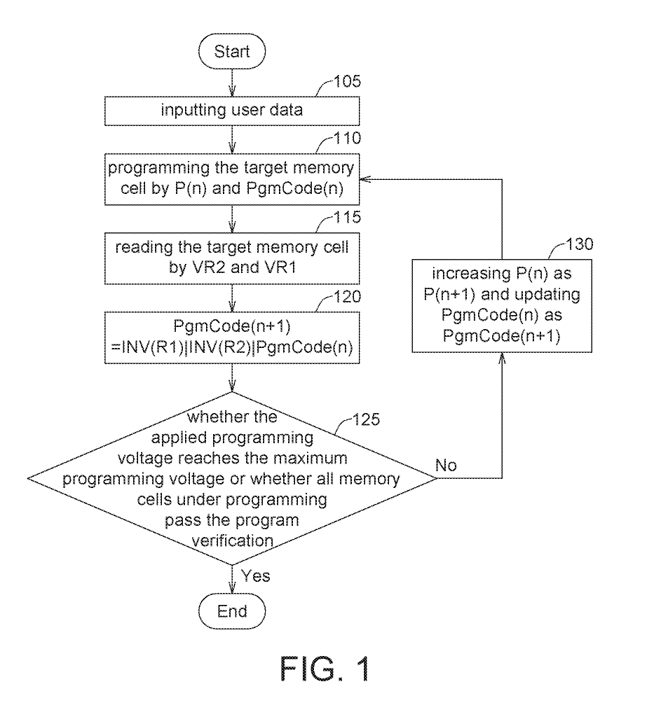

FIG. 1 shows a programming method for a memory device according to a first embodiment of the application. FIG. 1 may be used in for example but not limited by a SLC (Single-level cell) memory device.

In step 105 of FIG. 1, user data is input to a target memory cell of a plurality of memory cells under programming. For example, if all memory cells of a page are to be programmed, then all memory cells of the page are programmed synchronously but each of the memory cells of the page is programmed based on individual bias voltages on bit lines. If the bias voltage on the bit line is 0V, then the memory cell is programmed. If the bias voltage on the bit line is the power source Vcc, then program on the memory cell is inhibited.

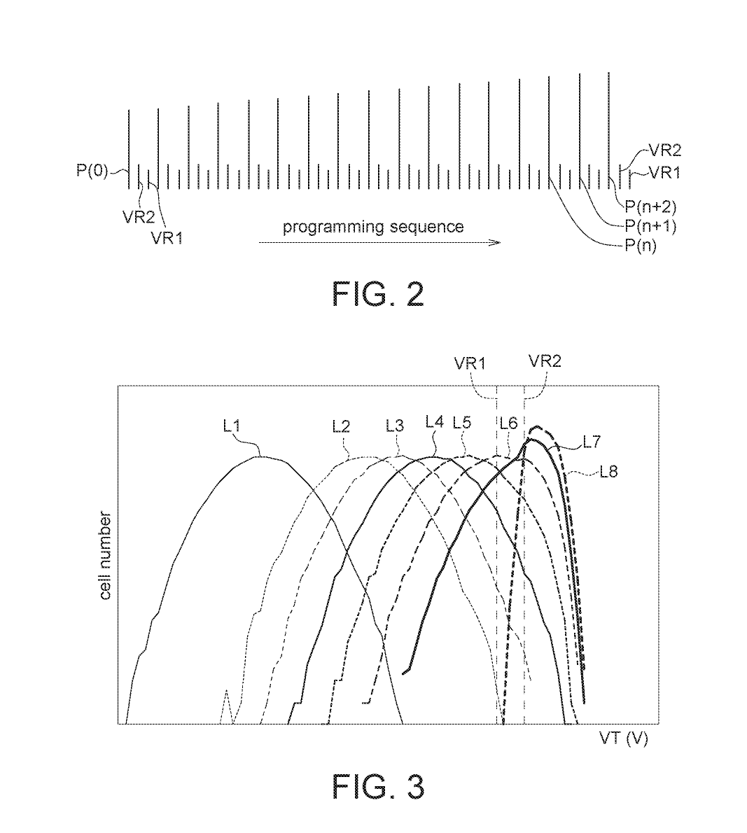

In step 110, the target memory cell is programmed by a programming voltage P(n) and a programming code PgmCode(n), wherein “n” is a positive integer. “n” has an initial value, for example but not limited by, 0. The programming voltage P(n) is shown in FIG. 2.

FIG. 2 shows a program sequence according to the first embodiment of the application. FIG. 3 shows Vt distribution of SLC memory cells, wherein the curves L1-L8 refer to respective Vt distribution caused by applying different programming voltages. As shown in FIG. 2 and FIG. 3, the first embodiment of the application applies ISPP, the programming voltages are incremental, for example but not limited by, in fixed steps. For example, in the programming voltage range of ISPR the programming voltages are increased in steps of 0.5V, That is, if the program voltage F(n) is 17V, then the program voltage P(n+1) is 17.5V. As shown in FIG. 2, in the first embodiment of the application, after the programming voltage P(n) is applied, the verification voltages VR2 and VR1 are applied (i.e. the first embodiment of the application applies 1P2V (one programming, two verifying), As described above, the program voltage P(n) is incremental, but the verification voltages VR2 and VR1 are fixed.

How to determine the programming code is as follows. For example but not limited by, in the initial (first) programming, the target memory cell is programmed by the initial program voltage P(0)(n=0) and the initial programming code PgmCode(0), wherein the program code PgmCode(0) is decided by the user data input in step 105 (i.e. PgmCode(0)=user data).

In step 115, the verification voltages VR2 and VR1 are applied in the target memory cell to read the target memory cell for obtaining two read data.

In step 120, the next program code PgmCode(n+1) may be obtained by:

PgmCode(n+1)=INV(R1)|INV(R2)|PgmCode(n) (or said PgmCode(n+1)={INV(R1) or INV(R2) or PgmCode(n)}).

R1 and R2 refer to data read by applying the verification voltages VR1 and VR2, respectively. INV(R1) and INV(R2) refer to inversion of R1 and R2. If the program code PgmCode(n+1) is logic “1”, then the target memory cell pass the pseudo program verification in the first embodiment of the application. In details, when the program code PgmCode(n) is logic 0, if at least one of the INV(R1) and INV(R2) is logic 1 (i.e. at least one of data read by applying the verification voltages VR1 and VR2 is logic 0), then the target memory cell passes the pseudo program verification. After ISPP, if the threshold voltage of the target memory cell exceeds the smaller of the verification voltages VR1 and VR2, then the target memory cell passes the pseudo program verification.

Besides, in the first embodiment of the application, the verification voltage VR2 reads and/or verifies the target memory cell first, and then the verification voltage VR1 reads and/or verifies the target memory cell later, as shown in the program sequence in FIG. 2. The verification voltage VR2 may be also referred as an actual verification voltage and the verification voltage VR1 may be also referred as a pseudo verification voltage.

In the first embodiment of the application, after applying the programming voltages to the target memory cell, if the threshold voltage of the target memory cell exceeds the verification voltage VR2 (or said the actual verification voltage), then the target memory cell passes the actual program verification. If the target memory cell passes the actual program verification, the programming operation on the target memory cell is completed in the first embodiment.

Besides, after applying the programming voltage to the target memory cell, if the threshold voltage of the target memory cell exceeds the verification voltage VR1 (or said the pseudo verification voltage) but does not exceed the verification voltage VR2 (or said the actual verification voltage), then the target memory cell passes pseudo program verification but does not pass the actual program verification. In the first embodiment, after applying the programming voltages to the target memory cells, the threshold voltage of the target memory cell exceeds the verification voltage VR1 (or said the pseudo verification voltage). Then, due to the time dependent relaxation issue, the threshold voltage of the target memory cell may be shifted upwards and thus the threshold voltage of the target memory cell is changed to exceed the verification voltage VR2 (or said the actual verification voltage). Therefore, in the first embodiment of the application, when it is decided that the threshold voltage of the target memory cell exceeds the verification voltage VR1 (or said the pseudo verification voltage), it is determined that the target memory cell passes pseudo program verification and the programming operation on the target memory cell is completed.

As described above, in the first embodiment of the application, the programming voltages are not applied to the target memory cell which passes the pseudo program verification and/or the actual program verification.

In step 125, it is determined that whether the applied programming voltage reaches the maximum programming voltage or whether all memory cells under programming pass the program verification. If yes in step 125, then the flow ends. If no in step 125, then the flow proceeds to the step 130 where the programming voltage P(n) is increased as the programming voltage P(n+1) (for example, increased in a fixed step) and the programming code PgmCode(n) is updated as the programming code PgmCode(n+1). Then the flow returns to the step 110 where the target memory cell is programmed by the programming voltage P(n+1) and the programming code PgmCode(n+1).

In details, in step 125, deciding whether the applied programming voltage reaches the maximum programming voltage refers to that whether the applied programming voltage reaches the maximum programming voltage in the programming voltage range.

Also, in step 125, deciding whether all memory cells under programming passes the program verification refers to that if, for example, all memory cell of one page is programmed, then it is determined that whether respective threshold voltages of all memory cells of the page are higher than any one of VR2 or VR1. If respective threshold voltages of all memory cells of the page are higher than any one of VR2 or VR1, then all memory cells of the page pass the program verification and thus the flow ends. If the threshold voltage of at least one of the memory cells of the page is still lower than VR2 and VR1, then the at least one of the memory cells of the page fails to pass the program verification and thus the flow proceeds to perform program and verification on the memory cells which fail to pass the program verification.

In FIG. 2 and FIG. 3, the actual verification voltage VR2 is higher than the pseudo verification voltage VR1. However, in other possible embodiment(s) of the application, the actual verification voltage VR2 may be lower than or equal to the pseudo verification voltage VR1, which is still within the spirit and scope of the application.

Further, in step 115 of FIG. 1, the target memory cell is read by the actual verification voltage VR2 first and then read by the pseudo verification voltage VR1. However, in other possible embodiment(s) of the application, the target memory cell is read by the pseudo verification voltage VR1 first and then read by the actual verification voltage VR2, which is still within the spirit and scope of the application.

Further, in the first embodiment of the application, the difference between the verification voltages VR2 and VR1 may be corresponding to the threshold voltage shift amount caused by the time dependent relaxation issue.

As described above, implementation in FIG. 1 to FIG. 3 of the first embodiment of the application may be used to address the time dependent relaxation issue of the flash memory. Therefore, it is easy to integrate implementation in FIG. 1 to FIG. 3 of the first embodiment of the application with current circuit design.

In the first embodiment of the application, by the 1P2V programming operation, the threshold voltage distribution of the memory cells may be tightened.

### Second Embodiment

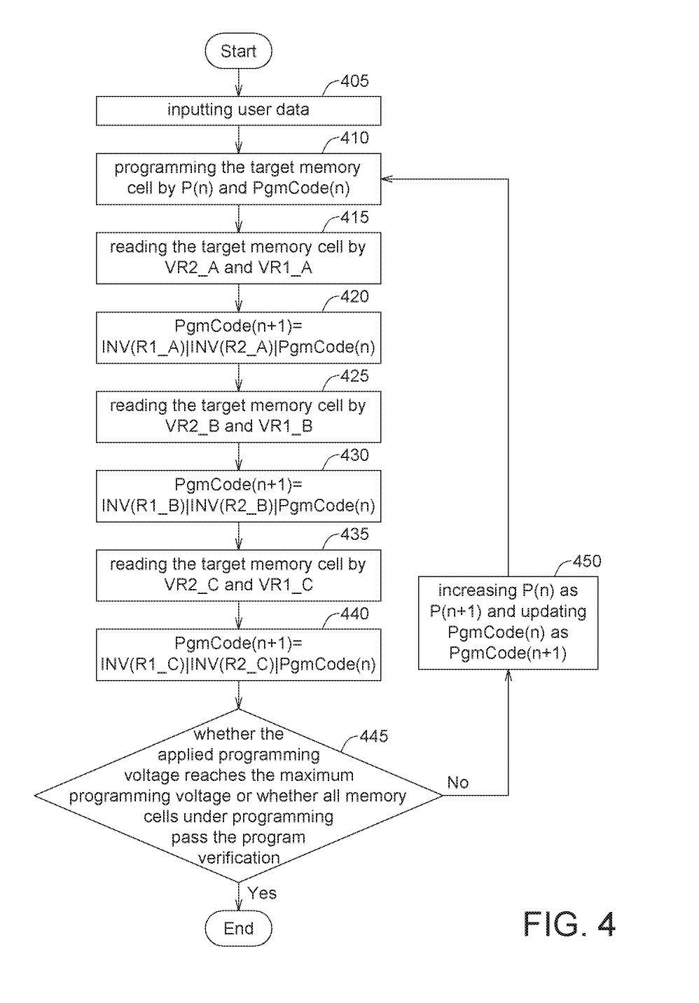

FIG. 4 shows a programming method for a memory device according to a second embodiment of the application. FIG. 4 may be used in for example but not limited by a MLC (Multi-level cell) memory device. Steps 405 and 410 are similar to the steps 105 and 110 of FIG. 1 and thus the details are omitted.

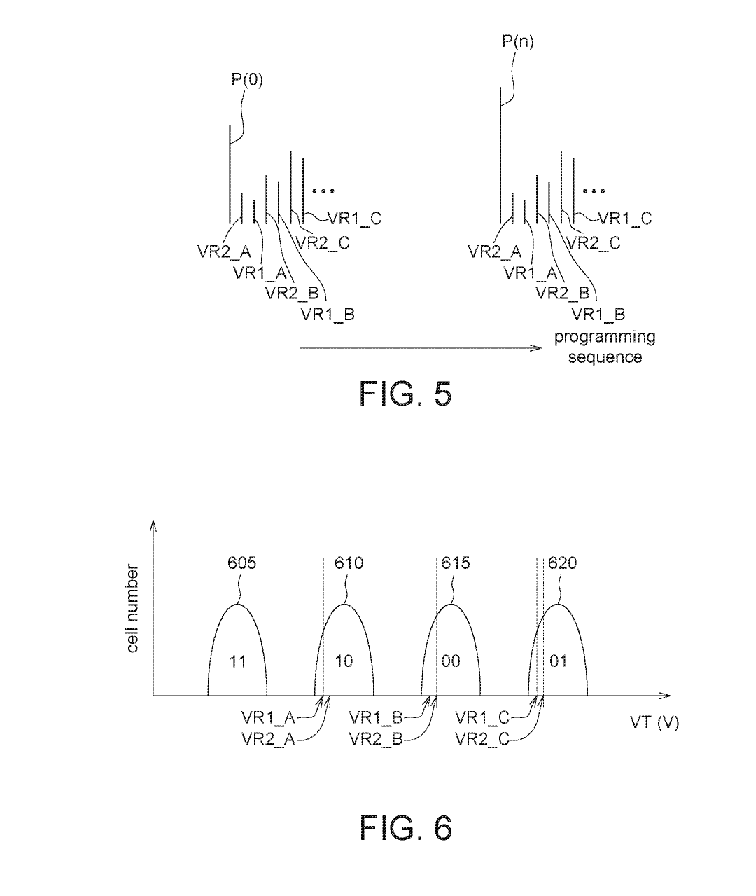

FIG. 5 shows a program sequence according to the second embodiment of the application. FIG. 6 shows Vt distribution of MLC memory cells. In FIG. 6, the range 605 refers to an erased state. If the threshold voltage of the memory cell is within the range 605, then the memory cell is programmed as the erased state (storing logic “11”). The range 610 refers to a first programmed state. If the threshold voltage of the memory cell is within the range 610, then the memory cell is programmed as the first programmed state (storing logic “10”). The range 615 refers to a second programmed state. If the threshold voltage of the memory cell is within the range 615, then the memory cell is programmed as the second programmed state (storing logic “00”). The range 620 refers to a third programmed state. If the threshold voltage of the memory cell is within the range 620, then the memory cell is programmed as the third programmed state (storing logic “01”).

As shown in FIG. 5 and FIG. 6, in the second embodiment of the application, after the programming voltage P(n) is applied, verification voltages VR2_A, VR1_A, VR2_B, VR1_B, VR2_C and VR1_C are applied (i.e. the second embodiment also applies 1P2V programming). The verification voltages VR2_A and VR1_A may be used to verify whether the target memory cell is within the range 610. The verification voltages VR2_B and VR1_B may be used to verify whether the target memory cell is within the range 615. The verification voltages VR2_C and VR1_C may be used to verify whether the target memory cell is within the range 620.

Of course, the programming voltage P(n) is incremental but the verification voltages VR2_A, VR1_A, VR2_B, VR1_B, VR2_C and VR1_C are fixed.

However to determine the programming code is as follows. For example but not limited by, in initial programming, the memory cells are programmed by the programming voltage P(0)(n=0) and the initial programming code PgmCode(0), wherein the programming code PgmCode(0) is determined by the user data input in the step 405.

Then, in step 415, the verification voltages VR2_A and VR1_A are applied to the target memory cell to read data R2_A and R1_A from the target memory cell.

In step 420, the next program code PgmCode(n+1) may be obtained by:

PgmCode(n+1)=INV(R1_A)|INV(R2_A)|PgmCode(n) (or said, PgmCode(n+1)={INV(R1_A) or INV(R2_A) or PgmCode(n)}.

R1_A and R2_A refer to data read by applying the verification voltages VR1_A and VR2_A, respectively. INV(R1_A) and INV(R2_A) refer to inversion of R1_A and R2_A. If the program code PgmCode(n+1) is logic “1”, then the target memory cell pass the pseudo program verification. The symbols R1_B, R2_B, INV(R1_B), INV(R2_B), R1_C, R2_C, INV(R1_C) and INV(R2_C) refer to similar meaning.

Further, in the second embodiment, based on the user data input in the step 405, whether the programming code PgmCode(n+1) obtained in the step 420 is used is determined. That is, if the user data is logic “10” (which means the target memory cell should be programmed as logic “10” (i.e. the range 610 in FIG. 6)), then the programming code PgmCode(n+1) obtained in the step 420 is used in determining the next programming code PgmCode(n+1), On the contrary, if the user data is not logic “10”, then the programming code PgmCode(n+1) obtained in the step 420 is not used in determining the next programming code PgmCode(n+1) (i.e. the programming code PgmCode(n+1) obtained in the step 420 is ignored).

The steps 425, 430, 435 and 440 are similar to the steps 415 and 420. Similarly, based on the user data input in the step 405, whether the programming code PgmCode(n+1) obtained in the step 430 is used is determined. That is, if the user data is logic “00” (which means the target memory cell should be programmed as logic “00” (i.e. the range 615 in FIG. 6)), then the programming code PgmCode(n+1) obtained in the step 430 is used in determining the next programming code PgmCode(n+1). On the contrary, if the user data is not logic 00″, then the programming code PgmCode(n+1) obtained in the step 430 is not used in determining the next programming code PgmCode(n+1) (i.e. the programming code PgmCode(n+1) obtained in the step 430 is ignored).

Similarly, based on the user data input in the step 405, whether the programming code PgmCode(n+1) obtained in the step 440 is used is determined. That is, if the user data is logic “01” (which means the target memory cell should be programmed as logic “01” (i.e., the range 620 in FIG. 6)), then the programming code PgmCode(n+1) obtained in the step 440 is used in determining the next programming code PgmCode(n+1). On the contrary, if the user data is not logic “01”, then the programming code PgmCode(n+1) obtained in the step 440 is not used in determining the next programming code PgmCode(n+1) (i.e. the programming code PgmCode(n+1) obtained in the step 440 is ignored).

Steps 445 and 450 are similar to steps 125 and 130 of FIG. 1.

Similarly, in FIG. 5 and FIG. 6, the actual verification voltages VR2_A, VR2_B and VR2_C are higher than the pseudo verification voltages VR1_A, VR1_B and VR1_C, respectively. However, in other possible embodiments of the application, the actual verification voltages VR2_A, VR2_B and VR2_C may be lower than or equal to the pseudo verification voltages VR1_A, VR1_B and VR1_C, respectively, which is still within the spirit and scope of the application.

Further, in steps 415, 425 and 435 of FIG. 4, the target memory cell is read by applying the actual verification voltages VR2_A, VR2_B and VR2_C and then read by applying the pseudo verification voltages VR1_A, VR1_B and VR1_C. However, in other possible embodiments of the application, the target memory cell is read by applying the pseudo verification voltages VR1_A, VR1_B and VR1_C and then read by applying the actual verification voltages VR2_A, VR2_B and VR2_C, which is still within the spirit and scope of the application.

In the second embodiment of the application, by the 1P2V programming operation, the threshold voltage distribution of the memory cells may be tightened.

### Third Embodiment

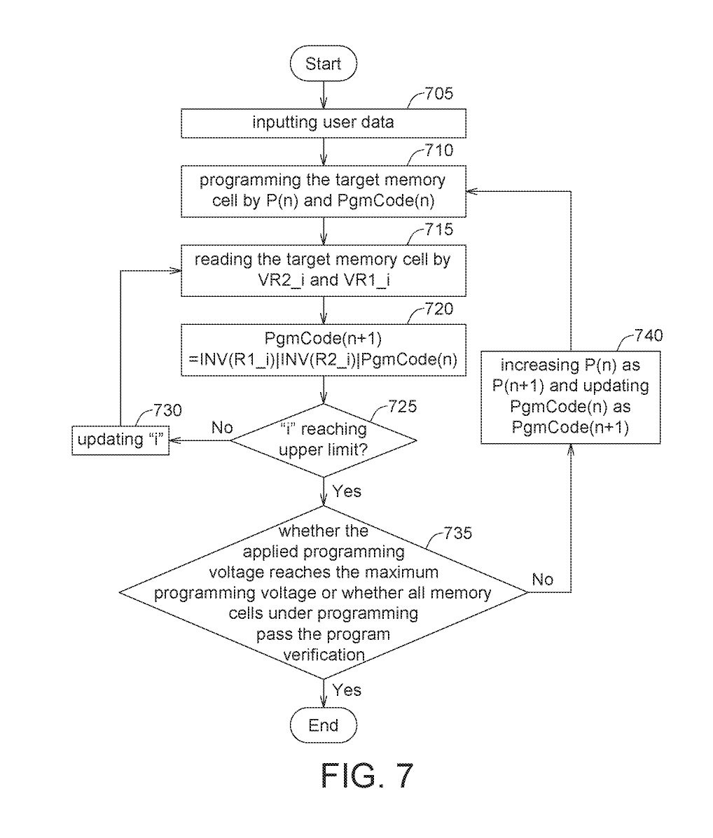

FIG. 7 shows a programming method for a memory device according to a third embodiment of the application. FIG. 7 may be used in for example but not limited by a TLC (Triple-level cell) memory device. Steps 705 and 710 are similar to the steps 105 and 110 of FIG. 1 and thus the details are omitted.

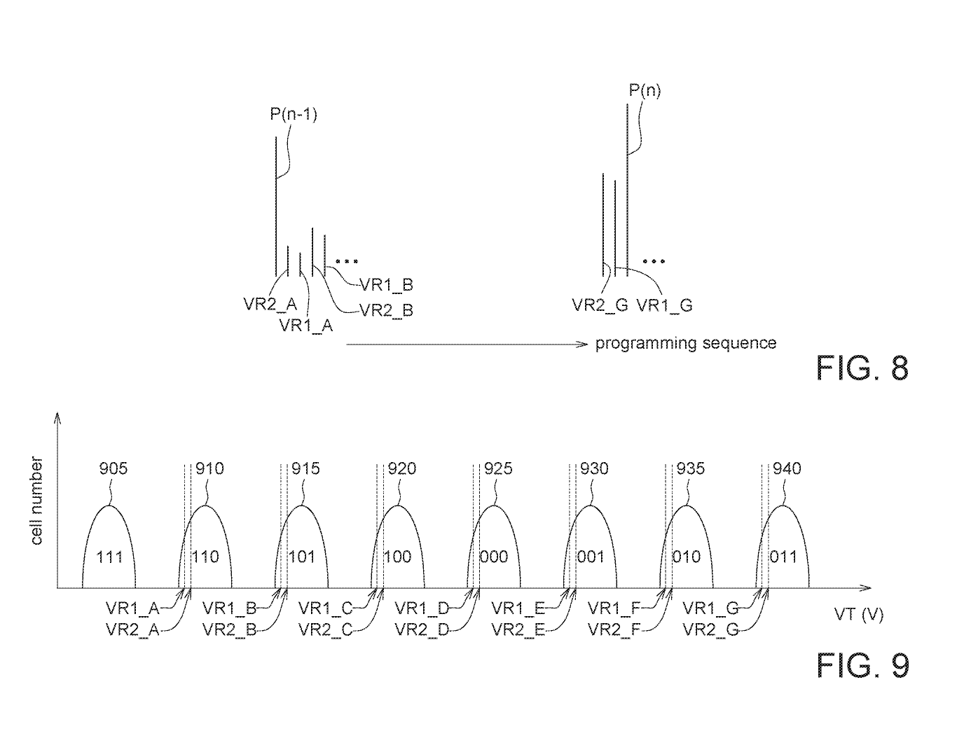

FIG. 8 shows a program sequence according to the third embodiment of the application. FIG. 9 shows Vt distribution of TLC memory cells. In FIG. 9, the range 905-940 refers to different states. For example, if the threshold voltage of the memory cell is within the range 915, then the memory cell is programmed as logic “101”). Others are similar.

As shown in FIG. 8 and FIG. 9, in the third embodiment of the application, after the programming voltage P(n) is applied, a plurality of verification voltages VR2_A, VR1_A, . . . , VR2_G and VR1_G are applied (i.e. the third embodiment also applies 1P2V programming). The verification voltages VR2_A and VR1_A may be used to verify whether the target memory cell is within the range 910. Others are similar.

Of course, the programming voltage P(n) is incremental but the verification voltages VR2_A, VR1_A, VR2_G and VR1_G are fixed.

However to determine the programming code is as follows. For example but not limited by, in initial programming, the memory cells are programmed by the programming voltage P(0)(n=0) and the initial programming code PgmCode(0), wherein the programming code PgmCode(0) is determined by the user data input in the step 705.

Then, in step 715, the verification voltages VR2_i and VR1_i (i=A to G) are applied to the target memory cell to read data R2_i and R1_i from the target memory cell.

In step 720, the next program code PgmCode(n+1) may be obtained by:

PgmCode(n+1)=INV(R1_i)|INV(R2_i)|PgmCode(n) (or said, PgmCode(n+1)={INV(R1_i) or INV(R2_i) or PgmCode(n)}.

R1_i and R2_i refer to data read by applying the verification voltages and VR2_i, respectively. INV(R1_i) and INV(R2_i) refer to inversion of R1_i and R2_i. If the program code PgmCode(n+1) is logic “1”, then the target memory cell pass the pseudo program verification.

Further, in the third embodiment, based on the user data input in the step 705, whether the programming code PgmCode(n+1) obtained in the step 720 is used is determined. That is, for example, if the user data is logic “110” (which means the target memory cell should be programmed as logic “110” (i.e., the range 910 in FIG. 6)), then the programming code PgmCode(n+1) (i=A) obtained in the step 720 is used in determining the next programming code PgmCode(n+1) and other programming code PgmCode(n+1) (i=B to G) obtained in the step 720 is not used in determining the next programming code PgmCode(n+1).

In step 725, it is determined whether the parameter “i” reaches upper limit (the upper limit of the parameter “i” is G). If no in step 725, then the parameter “i” is updated in step 730 (that is, if the current parameter “i” is A, then the parameter “i” is updated as B). If yes in step 725, then the flow proceeds to step 735. Steps 735 and 740 are similar to steps 125 and 130.

Similarly, in FIG. 8 and FIG. 9, the actual verification voltage VR2_i is higher than the pseudo verification voltage VR1_j. However, in other possible embodiments of the application, the actual verification voltage VR2_i may be lower than or equal to the pseudo verification voltage VR1_i, which is still within the spirit and scope of the application.

Further, in steps 715 of FIG. 7, the target memory cell is read by applying the actual verification voltage VR2_i and then read by applying the pseudo verification voltage VR1_i. However, in other possible embodiments of the application, the target memory cell may be read by applying the pseudo verification voltage VR1_i and then read by applying the actual verification voltage VR2_i, which is still within the spirit and scope of the application.

In the third embodiment of the application, by the 1P2V programming operation, the threshold voltage distribution of the memory cells may be tightened.

Further, the above embodiments also provide performing a programming operation and a program-verification operation on the target memory cell. The programming operation and the programming-verification operation including: applying a plurality of programming voltages P(n), a plurality of first verification voltages (VR1, VR1_A, . . . , VR1_G) and a plurality of second verification voltages (VR2, VR2_A, . . . , VR2_G) on the target memory cell. Details are as described above.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A method for programming a memory device, comprising:
programming a target memory cell by a programming voltage and a programming code;
applying first and second verification voltages on the target memory cell to obtain first and second read data; and
determining whether the target memory cell pass an actual programming verification and/or a pseudo programming verification based on the programming code, the first and the second read data.

2. The method of claim 1, wherein
a next programming code is obtained based on an inverted data of the first read data, an inverted data of the second read data or the programming code; and
whether to program the target memory cell is based on a bit line bias voltage of the target memory cell.

3. The method of claim 2, wherein
if the applied programming voltage does not reach a maximum programming voltage, or the target memory cell fails to pass any one of the actual programming verification and the pseudo programming verification,
the programming voltage is increased and the programming code is updated as the next programming code; and
the target memory cell is programmed by the increased programming voltage and the next programming code.

4. The method of claim 3, wherein in applying the first and the second verification voltages, the second verification voltage is applied to read the target memory cell first and then the first verification voltage is applied to read the target memory cell.

5. The method of claim 3, wherein in applying the first and the second verification voltages, the first verification voltage is applied to read the target memory cell first and then the second verification voltage is applied to read the target memory cell.

6. The method of claim 1, wherein when a threshold voltage of the target memory cell exceeds the first verification voltage but does not exceed the second verification voltage, then the target memory cell passes the pseudo program verification and a programming operation on the target memory cell is completed.

7. The method of claim 1, wherein when a threshold voltage of the target memory cell exceeds the second verification voltage, then the target memory cell passes the actual program verification and a programming operation on the target memory cell is completed.

8. A method for programming a memory device, comprising:
executing a programming operation and a programming-verification operation on a target memory cell, the programming operation and the programming-verification operation including: applying a plurality of programming voltages, a plurality of first verification voltages and a plurality of second verification voltages on the target memory cell, wherein each of the first verification voltages and each of the second verification voltages is corresponding to a time dependent relaxation; and
determining whether a threshold voltage of the target memory cell passes each of the first verification voltages and/or each of the second verification voltages to determine whether the target memory cell is successfully programmed.

9. The method of claim 8, wherein in the programming operation and the programming-verification operation, the second verification voltage is applied to read the target memory cell first and then the first verification voltage is applied to read the target memory cell.

10. The method of claim 8, wherein in the programming operation and the programming-verification operation, the first verification voltage is applied to read the target memory cell first and then the second verification voltage is applied to read the target memory cell.

11. The method of claim 8, wherein when the threshold voltage of the target memory cell exceeds each of the first verification voltages but does not exceed each of the second verification voltages, then the target memory cell passes a pseudo program verification and a programming operation on the target memory cell is completed.

12. The method of claim 8, wherein when the threshold voltage of the target memory cell exceeds each of the second verification voltages, then the target memory cell passes an actual program verification and a programming operation on the target memory cell is completed.

13. The method of claim 8, wherein whether to program the target memory cell is based on a bit line bias voltage of the target memory cell.
